(19) United States
(12) Patent Application Publication
(10) Pub. No.: US 2017/0059402 A1
(43) Pub. Date: Mar. 2, 2017

(54) DEVICE AND IMAGE SENSOR

(71) Applicant: CANON KABUSHIKI KAISHA, Tokyo (JP)

(72) Inventor: Alexis Debray, Tokyo (JP)

(21) Appl. No.: 15/238,453

(22) Filed: Aug. 16, 2016

(30) Foreign Application Priority Data
Aug. 28, 2015 (JP) 2015-168427

(51) Int. Cl. G01J 1/44; G01J 1/04; H01L 27/146

(52) U.S. Cl. CPC G01J 1/44; H01L 27/14629; H01L 27/14636; H01L 27/14649; G01J 1/0407

(57) ABSTRACT

Provided is a device, which is configured to emit or receive an electromagnetic wave, including: a substrate; and an element provided on the substrate, the element including: an antenna; and an electronic element electrically connected to the antenna, and the substrate including: a recessed portion; a reflecting portion formed on a surface of the recessed portion; and a holding portion configured to hold the electronic element, the antenna including two portions opposed to each other, each of the two portions extending toward the electronic element and being electrically connected to the electronic element.

### BACKGROUND OF THE INVENTION

Field of the Invention

The present invention relates to a device configured to emit or detect an electromagnetic wave and an image sensor including the device.

Description of the Related Art

A terahertz wave is an electromagnetic wave having an arbitrary frequency band from a millimeter wave range to a terahertz wave range (30 GHz to 30 THz). Through arranging electromagnetic wave sensors that can detect a terahertz wave in an array and disposing a suitable focus lens in front thereof, an apparatus that can acquire an image of an object to be measured in the terahertz wave range can be constructed. Image acquisition in the terahertz wave range is useful in various fields. For example, a terahertz wave passes through cloth, fabric, and the like but does not pass through metal with ease, and thus, such an imaging apparatus is useful in the field of security, e.g., detection of a hidden weapon. The imaging apparatus is also useful in the field of medical care. For example, cancer tissue and healthy tissue have different refractive indices with respect to the terahertz wave, and thus, imaging of living tissue in the terahertz wave range is useful for detecting cancer cells of a patient.

In imaging using a sensor array, it is important that information to be detected by a sensor at a certain position is not detected by a sensor at another position. The reason is that such detection results in acquisition of an image that is different from an intended image. Further, nowadays, hundreds of sensors are integrated on a single semiconductor substrate. A semiconductor usually has a permittivity that is higher than that of air surrounding the sensors. As a result, received/emitted energy involving an antenna of a sensor integrated on a semiconductor substrate tends to propagate through the substrate rather than through the air. The semiconductor substrate usually has a planar shape, and thus, energy propagating through the substrate is in a substrate mode, that is, in a resonance mode, and thus, the energy propagates through the sensors in an unintentional way. This tends to result in a deformed image.

In US 2014/0117236, there is disclosed a detection device in the terahertz wave range. In this case, a thermal sensor and a wide-band planar skirt antenna are used to attain a low thermal capacity and high electrical performance. The antenna has a length that is substantially equivalent to one wavelength, and realizes impedance matching and high energy transmission efficiency with a 200Ω resistor. Further, in one embodiment, a detector includes a planar conductor acting as a reflector to improve the directivity of the antenna.

### SUMMARY OF THE INVENTION

In view of the above-mentioned problem, according to one aspect of the present invention, there is provided a device, which is configured to emit or receive an electromagnetic wave, including: a substrate; and an element provided on the substrate, the element including: an antenna; and an electronic element electrically connected to the antenna, and the substrate including: a recessed portion; a reflecting portion formed on a surface of the recessed portion; and a holding portion configured to hold the electronic element, the antenna including two portions opposed to each other, each of the two portions extending toward the electronic element and being electrically connected to the electronic element.

Further features of the present invention will become apparent from the following description of exemplary embodiments with reference to the attached drawings.

### BRIEF DESCRIPTION OF THE DRAWINGS

FIG. 1A is a top view of a device as a first example according to a first embodiment of the present invention.

FIG. 1B is a sectional view of the device as the first example taken along the line 1B-1B of FIG. 1A according to the first embodiment.

FIG. 1C is a sectional view for illustrating an example of a structure of a holding portion of a device according to the first embodiment.

FIG. 1D is a top view for illustrating another example of a structure of a holding portion of a device according to the first embodiment.

FIG. 1E is a sectional view of the device taken along the line 1E-1E of FIG. 1D according to the first embodiment.

FIG. 2A is a top view of a device as a second example according to the first embodiment.

FIG. 2B is a sectional view of the device as the second example taken along the line 2B-2B of FIG. 2A according to the first embodiment.

FIG. 3 is a top view for illustrating an energy distribution in a reception/emission pattern according to the first embodiment.

FIG. 4 is a side view for illustrating the energy distribution in the reception/emission pattern according to the first embodiment.

FIG. 5 is a perspective view for illustrating an antenna model exhibiting characteristics shown in Table 1.

FIG. 6 is a perspective view for illustrating an antenna model exhibiting characteristics shown in Table 2.

FIG. 7A is a top view of a device as a first example according to a second embodiment of the present invention.

FIG. 7B is a sectional view of the device as the first example taken along the line 7B-7B of FIG. 7A according to the second embodiment.

FIG. 8A is the top view of a device as a second example according to a second embodiment.

FIG. 8B is a sectional view of the device as the second example taken along the line 8B-8B of FIG. 8A according to the second embodiment.

FIG. 9 is an illustration of a current flow direction and null points of current when a loop antenna having a length of 3/2 wavelengths operates in the vicinity of a second anti-resonance frequency.

FIG. 10 is a top view for illustrating an energy distribution in a reception/emission pattern according to the second embodiment.

FIG. 11 is a side view for illustrating the energy distribution in the reception/emission pattern according to the second embodiment.

FIG. 12A is a top view of a device according to a third embodiment of the present invention.

FIG. 12B is a sectional view of the device taken along the line 12B-12B of FIG. 12A according to the third embodiment.

FIG. 13 is a top view for illustrating an energy distribution in a related-art reception/emission pattern.

FIG. 14 is a side view for illustrating the energy distribution in the related-art reception/emission pattern.

### DESCRIPTION OF THE EMBODIMENTS

In US 2014/0117236, neither how effectively an antenna is connected to a substrate nor a problem that may arise when such a connection is made is disclosed. In other words, in US 2014/0117236, the difficulty in forming a surface of the substrate as a planar conductor that acts as a reflector is not disclosed. Therefore, there is a case in which the power emitted by the antenna is not reflected by the planar conductor but propagates through the substrate. As a result, the emitted power is lower than that in a case in which the power emitted by the antenna is reflected by the planar conductor. Further, when a sensor array is used for forming an image, the energy received/emitted by the respective antennas that propagate through the substrate also propagates through other sensors, which may result in a deformed image.

The following embodiments relate to a device including an antenna as an electromagnetic wave reception/emission element and an electronic element. The following embodiments also relate to a device that operates in a terahertz wave range (THz wave range). In the following description, “detection/generation” refers to performing at least one of electromagnetic wave detection and electromagnetic wave generation. Further, “reception/emission” refers to performing at least one of electromagnetic wave reception and electromagnetic wave emission.

In the following embodiments, the device is configured so that leakage of energy received/emitted by the antenna into a substrate via a holding portion, which is disposed on a recessed portion of the substrate and is configured to hold the electronic element (reception/emission element), is reduced. Typically, the antenna includes two portions in the vicinity of the holding portion that are opposed to each other and that are electrically connected to the electronic element. The two portions extend from a principal portion of the antenna (region surrounded by a portion of the antenna except the two portions) toward the electronic element in a direction away from the principal portion. Alternatively, the holding portion can be formed as a cantilever portion extending from an edge portion of the substrate that defines the recessed portion and a reflecting portion may be provided also in a portion of the recessed portion under the cantilever portion as a unit configured to reflect received/emitted energy that attempts to leak into the substrate via the holding portion to reduce leakage into the substrate. A reverse tapered pillar portion and a reflective layer formed on a side wall surface therein can also be called a unit configured to reduce such leakage. An apparatus, e.g., an image sensor, formed through arranging a plurality of such electromagnetic wave detection/generation devices in an array on a common substrate can suppress signal leakage between within the sensor to improve the image quality.

Now, embodiments of the present invention are described with reference to the drawings. However, the present invention is not limited to the embodiments and various modifications and changes can be made without departing from the spirit of the present invention.

### First Embodiment

In a related-art structure, when an antenna is provided in contact with a substrate having a permittivity that is higher than that of a medium surrounding the antenna (usually, air or vacuum), at the time of emission, much of energy emitted from the antenna is emitted into the substrate and only a small amount thereof is emitted into the surrounding medium. As a result, in order to control a reception/emission pattern of the antenna, it is necessary to provide a lens on a backside of the substrate. For example, when the antenna is directly integrated on a silicon substrate, a silicon lens is often provided on the backside of the silicon substrate. However, when a plurality of antennas are arranged in an array in order to realize an image sensor, it is extremely complicated to design a single or a plurality of silicon lenses and focus an image onto the sensor array using the lenses.

One solution is to provide a metal surface between the antenna and the substrate. The metal surface acts as a reflector, and can direct the energy pattern received/emitted by the antenna above the substrate.

The antenna is usually coupled with an electronic element. When an electromagnetic wave is emitted, the electronic element is, for example, an oscillator. When the electromagnetic wave is received, the electronic element is, for example, a rectifier. Usually, the antenna and the electronic element are connected via a transmission line. However, in the terahertz wave range, a sufficiently satisfactory transmission line has not been developed yet, and thus, energy may be lost thereby. Specifically, impedance matching lacks among the electronic element, the transmission line, and the antenna, and there is a possibility that only part of energy is received/emitted by the antenna. Therefore, it is worthwhile trying to directly connect the antenna to the electronic element.

With regard to a structure of the electromagnetic wave detection/generation device, the antenna and the electronic element are directly connected. At the same time, a reflector is provided, and a pillar portion protruding from the reflector or the like is provided as a unit configured to hold the electronic element. However, a holding portion (electronic element support unit), e.g., a pillar portion, which houses the electronic element can be a hindrance to reflection in the reflector. Such a hindrance in the reflector can be a factor in leakage of part of energy received/emitted by the antenna into the substrate.

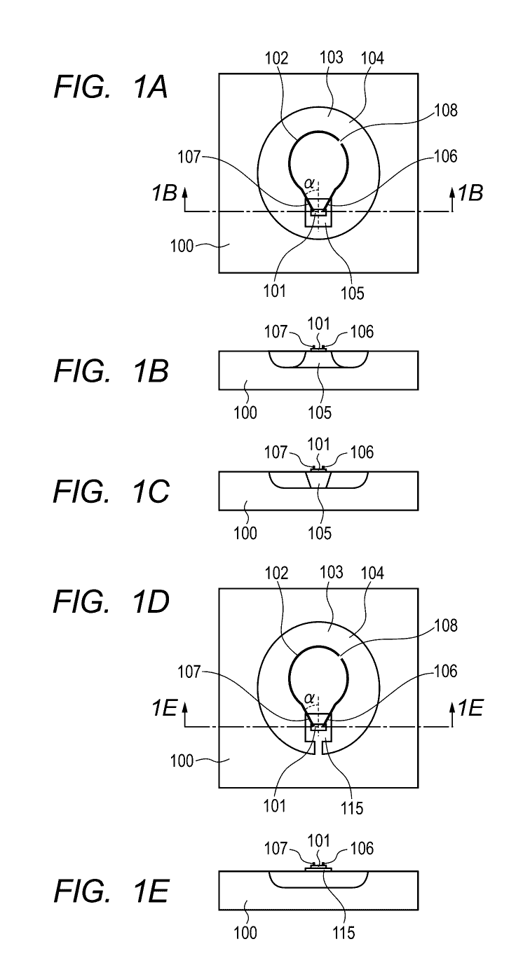

Accordingly, in a first example according to a first embodiment of the present invention, the shape of the antenna is modified as appropriate. Specifically, the shape of the antenna is designed so that leakage of energy received/emitted by the antenna into the substrate via the pillar portion configured to hold the electronic element is reduced. FIG. 1A is a top view of the device of the first example, and FIG. 1B is a sectional view taken along the line 1B-1B of FIG. 1A.

In this example, an electronic element 101 is integrated on a planar semiconductor substrate 100 of silicon or the like. Further, in order to reflect energy received/emitted by an annular closed loop-like antenna 102 formed of metal wire or the like, a metal reflector 104 is formed on a bottom surface and a side surface of a recessed portion 103 formed at a place recessed from a surface of the substrate 100. The antenna may have a polygon shape such as a rectangle or a triangle. The design of the antenna may be performed as appropriate depending on the circumstances. In this case, the substrate is planar, and the antenna is provided parallel to the surface of the substrate.

As illustrated in FIG. 1A, the recessed portion 103 is formed so as to surround the antenna 102 when seen from above the substrate 100. Further, in order to electrically connect the antenna 102 directly to the electronic element 101, the electronic element 101 is provided on a pillar portion (a holding portion) 105 that is connected to the substrate 100 and that protrudes from the reflector 104. The electronic element 101 is formed through, for example, being grown on the pillar portion 105 connected to the semiconductor substrate 100. In this example, in order to prevent part of energy received/emitted by the antenna from leaking into the substrate 100 via the pillar portion 105, two portions (linear opposed portions) 106 and 107 are formed in the antenna 102.

More specifically, parts of the antenna 102 in the vicinity of the pillar portion 105 having the electronic element 101 mounted thereon are the two linear (in this case, straight line shapes) portions 106 and 107. As illustrated in FIG. 1A, when an angle formed between a center line from the electronic element toward a barycenter of the antenna shown by the broken line and each of the two portions 106 and 107 is represented by α, the two portions 106 and 107 are flush with and are opposed to each other, and extend with an angle 2α formed therebetween. Those linear opposed portions are opposed to each other over a predetermined length that affects the characteristics of the antenna 102, and thus, the barycenter of the antenna is shifted to a direction away from the pillar portion 105.

Specifically, each of the two portions 106 and 107 straddles an edge of the pillar portion 105 on the side of the principal portion of the antenna 102 (region surrounded by the portion of the antenna 102 except the two portions 106 and 107), and extends from the principal portion of the antenna 102 (that is also referred to as a principal portion of the reception/emission pattern by the antenna 102) toward the electronic element 101. At this time, each of the two portions 106 and 107 extends from a connecting portion thereof and the principal portion toward the electronic element 101 in a direction away from the principal portion. In other words, one end of each of the two portions 106 and 107 is connected to the principal portion of the antenna 102 and another end thereof is disposed away from and outside the principal portion. Therefore, basically, the two portions 106 and 107 and the electronic element 101 are disposed outside the principal portion of the antenna 102.

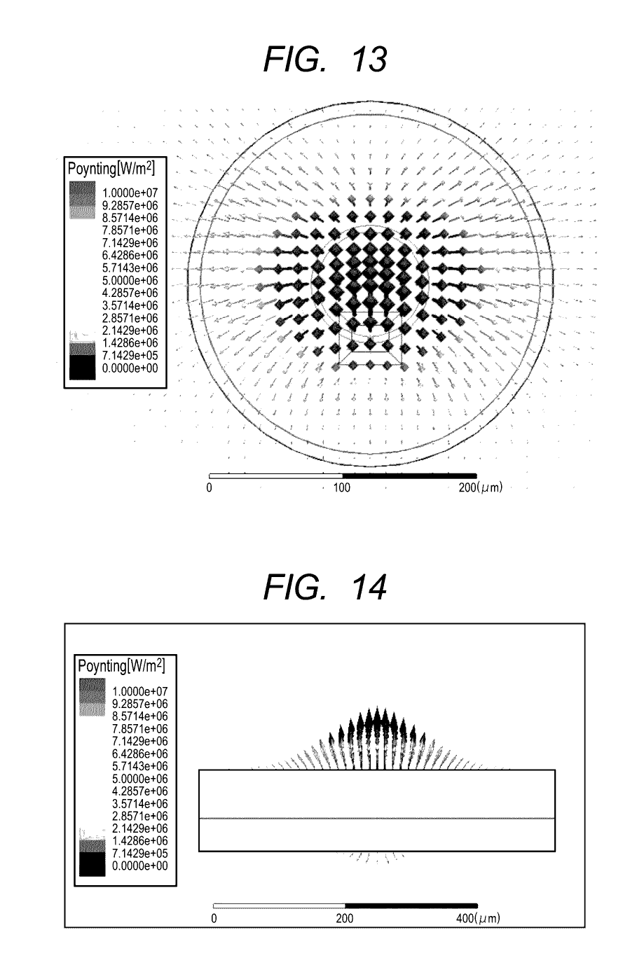

Therefore, the entire reception/emission pattern by the antenna is shifted in a direction away from the pillar portion 105 to reduce leakage of energy through the pillar portion. Further, current flow directions through the two portions 106 and 107 are opposite to each other, and thus, the reception/emission patterns produced by those currents are opposite to each other and part thereof are cancelled. Therefore, energy received/emitted by the antenna 102 in the vicinity of the pillar portion 105 is reduced to reduce leakage of energy received/emitted by the antenna through the pillar portion. This state is illustrated in FIG. 3 and FIG. 4 for illustrating a distribution of Poynting vectors of an electromagnetic wave emitted by the antenna. As can be seen from comparison with FIG. 13 and FIG. 14 for a related-art case, energy by the antenna 102 in the vicinity of the pillar portion 105 is reduced, and leakage of energy from the backside of the substrate is clearly reduced. Note that, the two portions 106 and 107 extend symmetrically with respect to the center line, but are not necessarily required to be symmetric. The shape may be designed as appropriate depending on the circumstances.

The first example according to the first embodiment is described as relating to a sensor. In this sensor, a rectifier 101 electrically connected to the antenna 102 is integrated on a silicon substrate. The rectifier is a Schottky barrier diode (SBD) or a field-effect transistor (FET). It is confirmed that both of the two operate at a frequency of 1 terahertz (THz) or higher. The latter (FET) uses a plasmon wave in a channel. The field-effect transistor can be manufactured as follows. First, the recessed portion 103 is formed through silicon wet etching or silicon dry etching. For example, a technology of silicon dry etching can form a reflector of various shapes. Then, the bottom surface and the side surface of the recessed portion are coated with a metal thin film through any one of metal vapor deposition and metal etching, metal vapor deposition and lithography, and metal vapor deposition and lift-off. Then, the recessed portion 103 is filled with a material having a low permittivity and being low-loss in the terahertz wave range (dielectric). For example, benzocyclobutene (BCB) is used. Then, the antenna 102 is formed on BCB using a known technique of semiconductor/metal vapor deposition, lithography, or lift-off.

When reception is made by the rectifier 101 that is a rectifier element as an electronic element, if the antenna 102 forms a closed circuit, an electric potential difference corresponding to a rectified signal may become zero. In order to avoid such a situation, a technique to form a cut 108 in the antenna 102 as illustrated in FIG. 1A is used. Further, when the cut 108 is made at a null point of current, the influences of the cut on an antenna impedance and on the reception/emission pattern are at the minimum. Using another circuit element instead of the cut can also obtain the same effect of holding the electric potential difference. Exemplary circuit elements include a resistor, a conductor, an inductor, and a combination thereof.

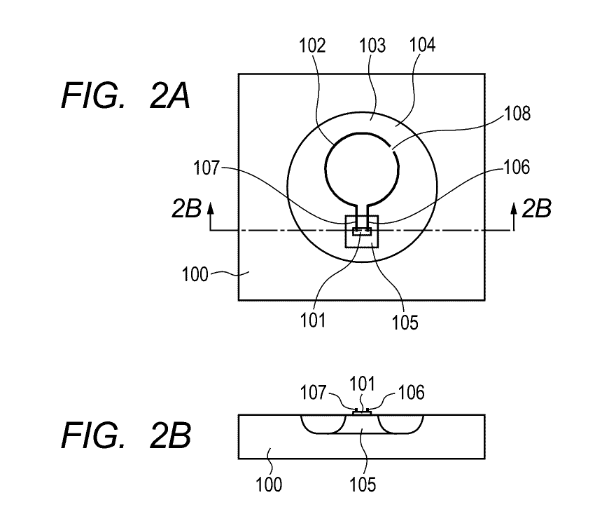

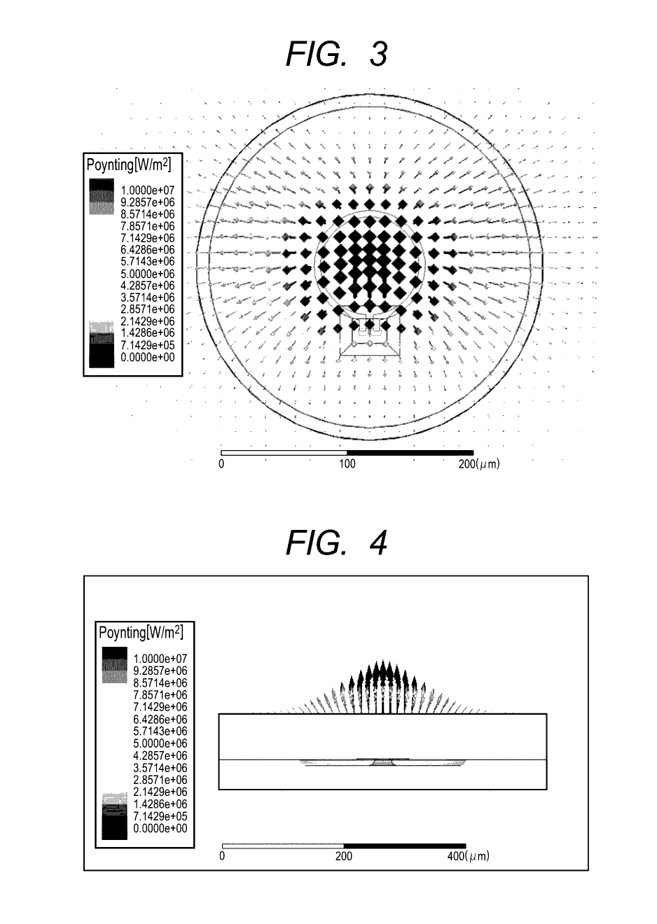

The influence of a parameter 2α on the characteristics of the detection/generation device is now described. FIG. 2A is a top view of a device in which the angle α is zero. FIG. 2B is a sectional view taken along the line 2B-2B of FIG. 2A. In such a structure, the directions of current flowing through the two portions 106 and 107 are exactly opposite to each other. As a result, reception/emission by the two portions 106 and 107 are exactly opposite to each other, and the effect is at the maximum. On the other hand, when the angle 2α is not zero, reception/emission by portions of the two portions 106 and 107 in a direction parallel to the center line (cos α) are opposite to each other, but reception/emission by portions of the two portions 106 and 107 in a direction perpendicular to the center line (sin α) are “constructive” to each other.

In order to reduce leakage of energy received/emitted by the antenna through the pillar portion, it is preferred to reduce the angle α to zero. However, when the two portions through which current in opposite directions flows are disposed in proximity to each other, electrical loss becomes larger than that in the case in which two such portions are disposed at a certain distance or at a certain angle. As linear opposed portions parallel to each other have a smaller length, the electrical loss becomes smaller. It follows that, when the antenna is designed, it is necessary to find a trade-off point between reduction in leakage of energy via the pillar portion and energy loss of the antenna based on the entire structure to which the antenna is applied.

In the case of a wire antenna, when the antenna has a length that is not smaller than the wavelength of the operating electromagnetic wave, the reception/emission impedance and the reception/emission pattern of the antenna depend on the length of the antenna. The reason is that a resonance or anti-resonance frequency appears for the electric potential difference along the antenna and the current through the antenna. A result of simulation of a closed loop antenna is as follows. When the antenna has a length that is approximately 3/2 of the operating wavelength, a second anti-resonance frequency appears. At this anti-resonance frequency, a real part of the reception/emission impedance exhibits a large peak, which is of importance. Various kinds of impedance loads and impedance matching are realized through various kinds of reception/emission impedances. Another technical advantage of the second anti-resonance frequency is that the reception/emission pattern is perpendicular to a plane defined by the antenna. As a result, when the antenna is disposed on the substrate, the antenna plane is parallel to the substrate surface, and the reception/emission pattern by the antenna is perpendicular to the substrate surface. This has a technical meaning when the antennas are arranged in an array for image sensing.

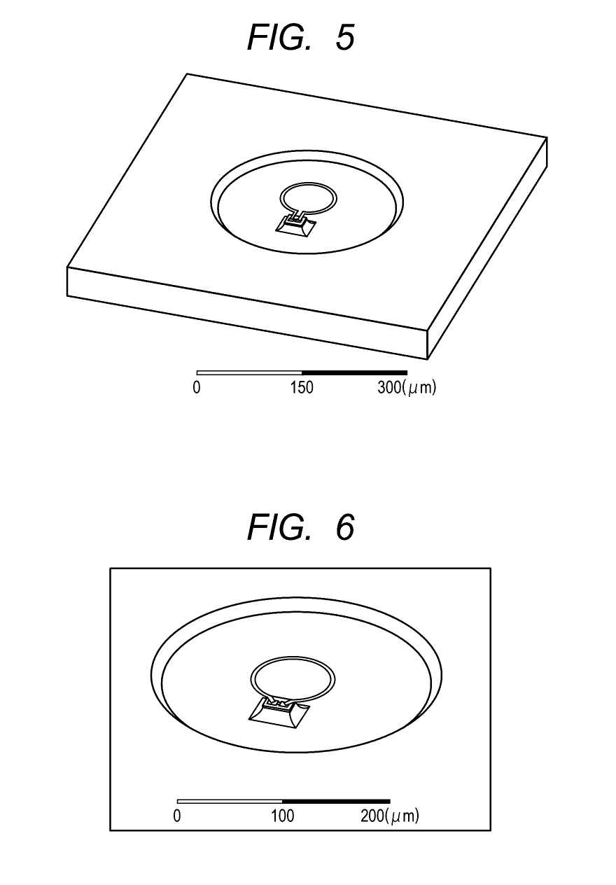

A result of simulation of an effect of this embodiment is now described. FIG. 5 is an illustration of a model of the antenna used for this purpose. The result of the simulation was obtained using a commercially available finite element method software HFSS (trade name; manufactured by ANSYS, Inc.). The simulation was done in the vicinity of 1 THz. With regard to parameters of the substrate, the material of the substrate was silicon and the material with which the recessed portion was filled was BCB. The entire length of the antenna was held to be 250 μm, and the length (l) of the two linear opposed portions of the antenna was varied between 0 μm and 47.5 μm inclusive. The ratio of energy received/emitted by/from below the model to energy received/emitted by/from above the model was calculated for two frequencies, that is, at the second anti-resonance frequency and at a frequency having an intensity of 30% of the peak intensity of the second anti-resonance frequency. The result is shown in Table 1 below. The result shows that the energy leakage ratio from the antenna into the substrate is reduced by providing the two linear opposed portions in the antenna. Further, the energy leakage ratio is reduced as the length of the two linear opposed portions increases. The reduction rate is approximately 37% at the second anti-resonance frequency, and is approximately 40% at the frequency having the 30% intensity.

This difference can be explained by difference in reception/emission pattern between the two frequencies. It can be seen that the reception/emission pattern of the original antenna without the linear opposed portions cannot be neglected for the effect of the present invention.

A result of simulation of the influence of the angle between the two portions is now described. FIG. 6 is an illustration of a model of the antenna used for this purpose. The method is almost the same as that used in the simulation above. The length (l) was fixed to 10 μm, and the angle α was varied between 0° and 45° inclusive. The result of the simulation is shown in Table 2 below. It can be seen that, as the angle α becomes larger, the leakage of energy received/emitted by/from the antenna into the substrate becomes larger.

[Table 1 and Table 2]

TABLE 1

| | Length l/μm | | | | |
|---|---|---|---|---|---|
| | 0 | 5 | 10 | 20 | 47.5 |
| Power ratio (%) at second | 12.2 | 9.5 | 7.9 | 7.9 | 7.7 |
| anti-resonance frequency | | | | | |
| Power ratio (%) at | 15.4 | 10 | 8.3 | 7.8 | 7.7 |
| frequency having 30% | | | | | |
| intensity | | | | | |

TABLE 2

| | Angle α/° | | |
|---|---|---|---|
| | 0 | 30 | 45 |
| Power ratio (%) at second | 7.9 | 11.1 | 13.3 |
| anti-resonance frequency | | | |
| Power ratio (%) at | 8.3 | 13.3 | 14.4 |
| frequency having 30% | | | |
| intensity | | | |

Table 1 shows that, without the two portions described above, the power ratio described above at the second anti-resonance frequency was 12.2%. Further, Table 2 shows that, when the two portions had a length of 10 μm and the angle α was 30°, the power ratio described above was 11.1%. However, when the angle α was 45°, the power ratio increased to 13.3%. It can be said that, when the angle 2α is larger than approximately 80°, the present invention has little effect. Therefore, it is preferred that the two portions extend with an angle of 80° or less formed therebetween.

A device according to this embodiment can reduce energy of the reception/emission pattern that attempts to propagate through the substrate in the vicinity of the holding portion.

In order to obtain the effect of reducing leakage of received/emitted energy into the substrate, it is not necessary that the two portions 106 and 107 have the straight line shapes. In order to obtain the effect, it is important that the two portions are opposed to each other. The reason is that the length of the two portions is considerably smaller than the operating wavelength.

In order to reduce leakage of received/emitted energy via the pillar portion, it is also effective to shape the pillar portion 105, as the holding portion, so as to be reverse tapered as illustrated in FIG. 1C. Alternatively, the holding portion can be formed as a cantilever portion 115 extending from an edge portion of the substrate 100 as illustrated in FIG. 1D and FIG. 1E. In this case, the reflecting portion 104 may be provided also in a portion of the recessed portion 103 under the cantilever portion 115 as a unit configured to reflect received/emitted energy that attempts to leak into the substrate 100 via the holding portion to reduce leakage into the substrate 100. The reason is that, with the reverse tapered shape in which the cross-sectional area increases from the bottom of the recessed portion toward the electronic element side, received/emitted energy coming to the pillar portion is reflected by a side wall of the pillar portion and propagates in a direction toward above the substrate. It is preferred that a reflective layer be formed on the side wall.

### Second Embodiment

When a plurality of antennas are arranged in an array to form an image sensor, in order to increase the resolution, it is important to reduce the antenna size. In the case of emission, there is a method in which, in order to increase the emitted power, emitters are arranged in an array. In this case, the reception/emission pattern can be controlled through adjusting the area of the emitter array. More specifically, when the area is reduced with respect to the wavelength, divergent emission can be realized. On the other hand, when the area is increased with respect to the wavelength, convergent emission can be realized. In a second embodiment of the present invention, the antenna size is reduced.

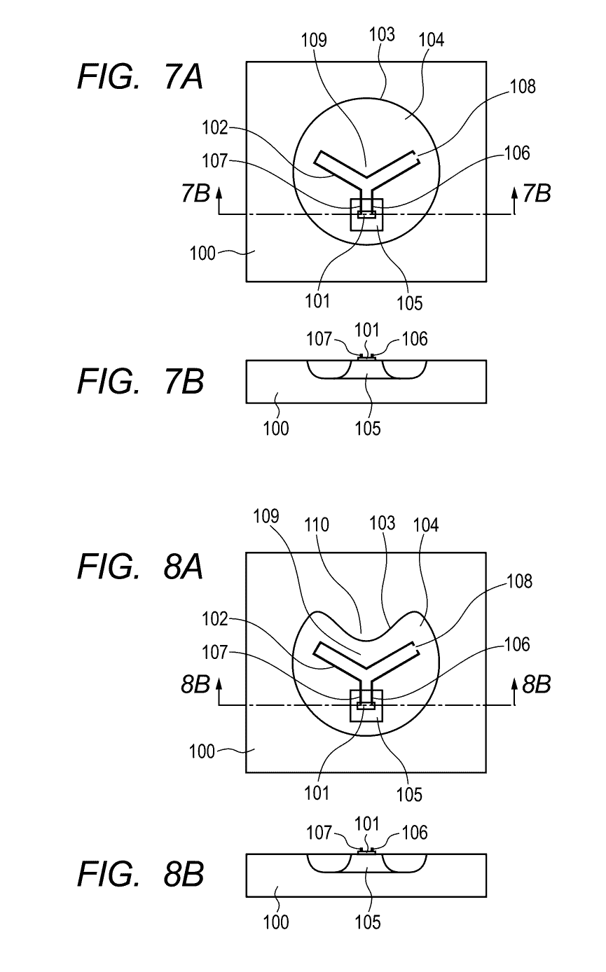

FIG. 7A and FIG. 7B are a top view for illustrating a structure of a device as a first example according to the second embodiment and a sectional view taken along the line 7B-7B, respectively. The electronic element 101 is integrated on the semiconductor substrate 100. In order to reflect energy received/emitted by the antenna 102, the recessed portion 103 and the metal reflector 104 are provided. The electronic element 101 is formed on the pillar portion 105 protruding from the recessed portion. The two are formed of a semiconductor. The antenna 102 includes the two portions 106 and 107 in the vicinity of the pillar portion 105. The two portions 106 and 107 are opposed to each other and extend outward from the principal portion of the antenna. In order to reduce the footprint of the antenna 102 (area of a region surrounded by the antenna 102 when the antenna 102 is projected onto the semiconductor substrate 100), the antenna 102 includes at least one concave portion 109 that is bent toward the principal portion of the antenna (region surrounded by a portion of the antenna except the two portions). The concave portion 109 is different from a concave portion involving the two portions 106 and 107. In other words, the antenna includes three concave portions in total including the concave portion 109. One concave portion among the three concave portions includes one of the two portions 106 and 107, and another concave portion includes another of the two portions 106 and 107.

The existence of the concave portion 109 causes the antenna 102 to include three wire portions opposed to one another to reduce the footprint thereof. With the operating wavelength at the second anti-resonance frequency, the current flow direction of one and the current flow direction of another of the two opposed wire portions forming the concave portion 109 are the same at the opposed portion, and thus, no loss is caused by the existence of the concave portion 109. In order to secure balance in shape of the reception/emission pattern of the antenna 102, it is preferred that the three opposed wire portions be disposed so as to form angles of substantially 120° therebetween.

Reducing the area of the antenna 102 is advantageous for reducing the size of one device. Further, in order to further reduce the device size, it is preferred to provide a concave portion 103 also in a recessed portion 104 so as to conform to the shape of the concave portion 109 of the antenna 102. A structure of the device in this second example is now described. FIG. 8A is a top view of the device as the second example, and FIG. 8B is a sectional view taken along the line 8B-8B of FIG. 8A. Also in the second example, the electronic element 101 is integrated on the semiconductor substrate 100. The recessed portion 104 and the metal reflector 103 are also provided. The electronic element 101 is provided on the pillar portion 105. The two portions 106 and 107 of the antenna 102 are provided in the vicinity of the pillar portion so as to be opposed to each other. Further, in order to reduce the area of the antenna 102, the concave portion 109 is provided in the antenna, and in addition, a concave portion 110 is provided in the recessed portion 104. The concave portion 109 and the concave portion 110 exert the effect of reducing the size. When the shape of the concave portion 110 geometrically conforms to the shape of the concave portion 109, this effect is more exerted.

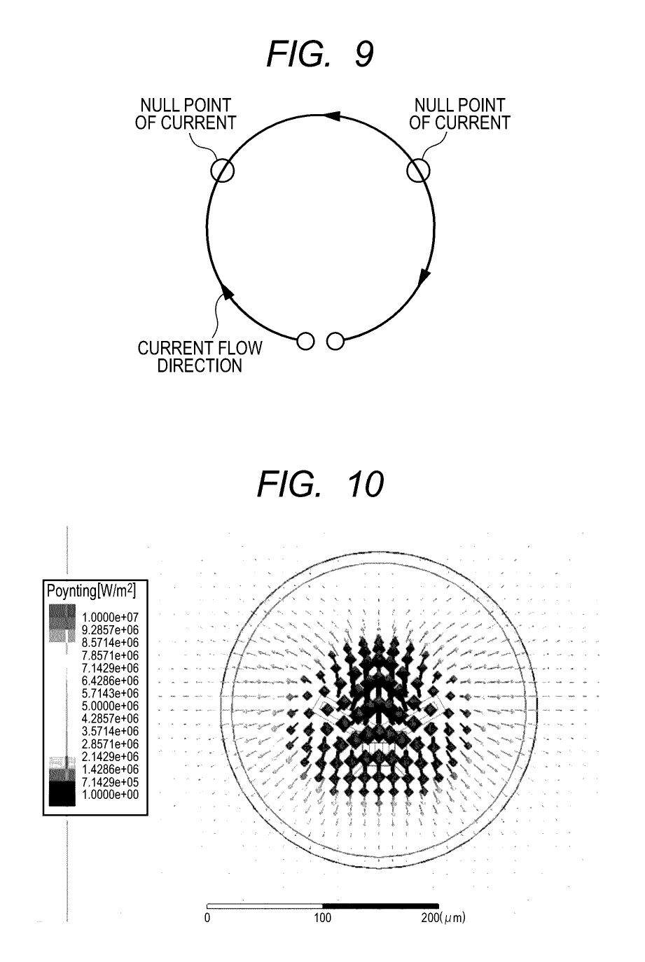

Also in the structure illustrated in FIG. 8A and FIG. 8B, when the current flow directions through the two portions 106 and 107 opposed to each other of the antenna 102 are opposite to each other, the energy loss of the antenna increases. Therefore, in order to reduce the loss of the antenna, it is preferred that the two opposed portions be short. On the other hand, current flows through two wire opposed portions of the antenna in the concave portion 109 (opposed portions except the two portions 106 and 107) in the following manner. When the loop-like antenna is driven in the vicinity of the second anti-resonance frequency, the antenna 102 has a length that is approximately 3/2 of the wavelength. FIG. 9 illustrates current flow directions in this case. When the current phase changes over time, the current flow directions also change, but the relative relationship therebetween (opposite directions or the same direction) does not change. Therefore, in the structure illustrated in FIG. 8A and FIG. 8B, the current flow directions through the two wire opposed portions of the antenna in the concave portion 109 are the same, and thus, no energy loss is caused.

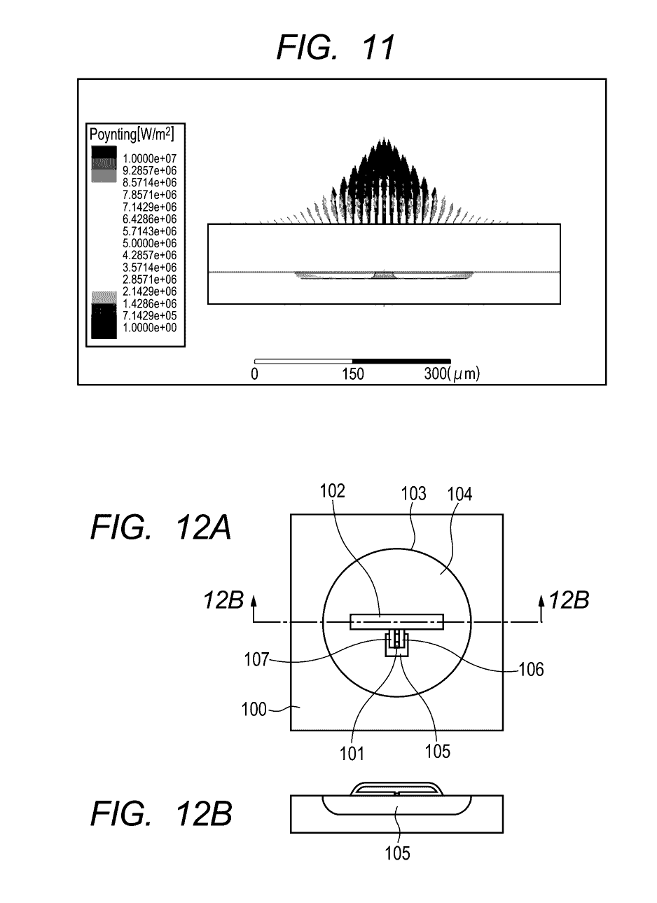

The state described above is illustrated in FIG. 10 and FIG. 11 for illustrating a distribution of Poynting vectors of an electromagnetic wave emitted by the antenna. Also in this case, as can be seen from comparison with FIG. 13 and FIG. 14 for the related-art case, energy by the antenna 102 in the vicinity of the pillar portion 105 is reduced, and leakage of energy from the backside of the substrate is clearly reduced.

A device according to this embodiment can reduce energy of the reception/emission pattern that attempts to propagate through the substrate in the vicinity of the holding portion.

### Third Embodiment

In a third embodiment of the present invention, an operating point of the wire antenna is in the vicinity of a first anti-resonance frequency. A real part of the reception/emission impedance of the antenna exhibits a peak not at the second anti-resonance frequency but at the first anti-resonance frequency. The value of the real part of the reception/emission impedance of the antenna permits use of loads having various impedances. However, differently from the case of the second anti-resonance frequency, the reception/emission pattern at the first anti-resonance frequency is along the plane defined by the antenna. As a result, when the antenna is disposed on the substrate, in order to separate the reception/emission pattern of the antenna from the surface of the substrate, it is preferred to provide the antenna perpendicularly to the surface of the substrate. In other words, it is preferred to provide the antenna 102 in a standing state on the surface of the substrate 100.

With the operating wavelength at the first anti-resonance frequency defined by the antenna, the antenna has a length that is approximately half the wavelength. In this case, a material surrounding the antenna is taken into consideration. This is the same with regard to the embodiments described above. For example, this is the same as in a case in which the antenna 102 has different lengths between when the antenna is in contact with BCB in the recessed portion and when the antenna is surrounded by air. Also in this embodiment, it is important to prevent leakage of energy received/emitted by the antenna 102 via the pillar portion 105 in a way similar to the above. In order to attain this, in the wire antenna, the two portions 106 and 107 opposed to each other are disposed in the vicinity of the pillar portion 105.

FIG. 12A and FIG. 12B are a top view for illustrating a structure of a device according to the third embodiment and a sectional view of the device taken along the line 12B-12B, respectively. The electronic element 101 is integrated on the semiconductor substrate 100. The recessed portion 103 and the metal reflector 104 are also provided. The electronic element 101 is provided on the pillar portion 105. The length of the antenna 102 is set so that the antenna 102 operates in the vicinity of the first anti-resonance frequency. The third embodiment is characterized in that the antenna 102 is provided in a standing state on the substrate surface. As described above, when the two portions 106 and 107 of the antenna 102 are parallel to each other, the effect of preventing leakage of received/emitted energy via the pillar portion 105 becomes greater. However, in order to reduce energy loss, similarly to the first embodiment, the angle 2α between the two portions can be adjusted. In this embodiment, the antenna 102 has a ribbon-like shape having a certain width, but the antenna 102 may be a wire antenna.

The described examples of the detection device can be applied or adapted to an electromagnetic wave generating device owing to the equivalence in configuration between an electromagnetic wave generating device that uses an antenna and an electromagnetic wave detecting device that uses an antenna. The electronic element in the electromagnetic wave generating device is an oscillator, e.g., a resonant tunneling diode (RTD).

A device according to this embodiment can reduce energy of the reception/emission pattern that attempts to propagate through the substrate in the vicinity of the holding portion.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-168427, filed Aug. 28, 2015, which is hereby incorporated by reference herein in its entirety.

What is claimed is:

1. A device, which is configured to emit or receive an electromagnetic wave, comprising:
a substrate; and
an element provided on the substrate,
the element comprising:
an antenna; and
an electronic element electrically connected to the antenna, and
the substrate comprising:
a recessed portion;
a reflecting portion formed on a surface of the recessed portion; and
a holding portion configured to hold the electronic element,
the antenna comprising two portions opposed to each other, each of the two portions extending toward the electronic element and being electrically connected to the electronic element.

2. The device according to claim 1, wherein each of the two portions is connected to the electronic element disposed outside a region surrounded by a portion of the antenna except the two portions.

3. The device according to claim 1, wherein the holding portion comprises a pillar portion protruding from a bottom surface of the recessed portion.

4. The device according to claim 3, wherein the pillar portion has a reverse tapered shape having a cross-sectional area that increases from the bottom surface of the recessed portion toward the electronic element side.

5. The device according to claim 1, wherein the holding portion comprises a cantilever portion extending from an edge portion of the substrate that defines the recessed portion.

6. The device according to claim 1, wherein the two portions extend with an angle of 80° or less formed therebetween.

7. The device according to claim 1, wherein the two portions are parallel to each other.

8. The device according to claim 1, wherein each of the two portions extends over an edge of the holding portion on a side of a region surrounded by a portion of the antenna except the two portions.

9. The device according to claim 1, wherein the antenna has a closed loop shape.

10. The device according to claim 9, wherein the antenna comprises a concave portion that is bent toward a region surrounded by a portion of the antenna except the two portions.

11. The device according to claim 10,
wherein the concave portion included in the antenna comprises three concave portions, and
wherein the three concave portions are disposed so as to form angles of substantially 120° therebetween.

12. The device according to claim 1, wherein the device is operated at a second anti-resonance frequency defined by the antenna.

13. The device according to claim 12,
wherein the substrate has a planar shape, and
wherein the antenna is provided so as to be parallel to a surface of the substrate.

14. The device according to claim 13, wherein the recessed portion is formed so as to surround the antenna as seen from above the substrate.

15. The device according to claim 1, which is operated at a first anti-resonance frequency defined by the antenna.

16. The device according to claim 15, wherein the antenna is disposed perpendicularly to a surface of the substrate.

17. The device according to claim 1, wherein each of the two portions has a straight line shape.

18. The device according to claim 1,
wherein the recessed portion is filled with a dielectric, and
wherein the antenna is provided on the dielectric.

19. A device, which is configured to emit or receive an electromagnetic wave, comprising:
a substrate; and
a reception/emission element provided on the substrate,
the reception/emission element comprising:
an antenna; and
an electronic element electrically connected to the antenna, and
the substrate comprising:
a recessed portion;
a reflecting portion formed on a surface of the recessed portion; and
a holding portion disposed on the recessed portion and configured to hold the electronic element,
at least one of the antenna or the holding portion being formed such that leakage of energy received or emitted by the antenna into the substrate via the holding portion is reduced.

20. An image sensor, comprising a plurality of devices provided on a common substrate,
each of the plurality of devices comprising the device of claim 1.

21. The image sensor according to claim 20,
wherein the electronic element comprises a rectifier element, and
wherein the antenna has a cut formed therein.
